(19) United States
(12) Patent Application Publication
(10) Pub. No.: US 2026/0130251 A1
(43) Pub. Date: May 7, 2026

(54) POWER SEMICONDUCTOR PACKAGES AND RELATED METHODS

(71) Applicant: SEMICONDUCTOR COMPONENTS INDUSTRIES, LLC, Scottsdale, AZ (US)

(72) Inventor: Christopher Lee TESSLER, Poughquag, NY (US)

(73) Assignee: SEMICONDUCTOR COMPONENTS INDUSTRIES, LLC, Scottsdale, AZ (US)

(21) Appl. No.: 18/936,068

(22) Filed: Nov. 4, 2024

(51) Int. Cl. H01L 23/498; H01L 21/48; H01L 23/00; H01L 23/13; H01L 23/14; H01L 23/31; H01L 25/07

(52) U.S. Cl. CPC H10W 70/685; H10W 70/05; H10W 70/095; H10W 70/65; H10W 70/68; H10W 70/698; H10W 74/114; H10W 90/00; H10W 72/07231

(57) ABSTRACT

Implementations of a substrate may include a semiconductor material; a redistribution layer coupled to a first largest planar surface of the semiconductor material; and a hollow via extending from a second largest planar surface of the semiconductor material completely through a thickness of the semiconductor material, the hollow via directly coupled with the redistribution layer.

### BACKGROUND

### 1. Technical Field

Aspects of this document relate generally to semiconductor package. More specific implementations involve power semiconductor packages.

### 2. Background

Semiconductor packages have been devised that work to provide mechanical support and protection for one or more semiconductor die included in the packages. Other semiconductor packages work to prevent damage to the semiconductor die from electrostatic discharge. Still other semiconductor packages work to assist with preventing damage to a semiconductor die included in the package from shock, vibration, or humidity.

### SUMMARY

Implementations of a substrate may include a semiconductor material; a redistribution layer coupled to a first largest planar surface of the semiconductor material; and a hollow via extending from a second largest planar surface of the semiconductor material completely through a thickness of the semiconductor material, the hollow via directly coupled with the redistribution layer.

Implementations of a substrate may include one, all, or any of the following:

The redistribution layer may include at least one thick copper layer.

The redistribution layer may include at least one dielectric layer and at least one layer of one of a solderable metal or a sinterable metal.

The semiconductor material may be thinned from an initial thickness.

The semiconductor material may be silicon carbide.

The semiconductor material may be silicon.

The substrate may include an oxide layer between the redistribution layer and the semiconductor material.

The substrate may include an oxide layer on the second largest planar surface of the semiconductor material.

The substrate may include a backmetal layer coupled to the second largest planar surface of the semiconductor material.

Implementations of a method of embedding a semiconductor die may include providing a silicon substrate including a first oxide layer thereon; forming at least one opening in the first oxide layer; etching a cavity into the silicon substrate at the at least one opening in the first oxide layer; forming a second oxide layer in the cavity; forming a thick copper layer on the first oxide layer and on the second oxide layer; and patterning the thick copper layer. The method may include sintering at least one semiconductor die to the thick copper layer in the cavity; filling a gap between the at least one semiconductor die and the thick copper layer in the cavity with a polyimide; forming a layer of photosensitive polymer over the at least one semiconductor die, the thick copper layer, and the first oxide layer; and patterning the layer of photosensitive polymer to form a plurality of openings therein. The method may include forming a first copper layer in the plurality of openings; and forming a second copper layer over the layer of photosensitive polymer and the first copper layer.

Implementations of a method of embedding a semiconductor die may include one, all, or any of the following:

Forming the first copper layer and forming the second copper layer may occur simultaneously.

The method may include forming a seed layer on the second oxide layer before forming the thick copper layer.

The method may include baking the polyimide.

The method may include coupling one of a redistribution layer or another semiconductor die to the second copper layer.

Implementations of a method of embedding a semiconductor die may include providing a silicon substrate including an oxide layer thereon; forming a thick copper layer on the oxide layer; patterning the thick copper layer; applying a first photosensitive polyimide over the thick copper layer; and patterning the first photosensitive polyimide to form an opening therein. The method may include one of sintering or soldering a semiconductor die in the opening; forming a first copper layer on the first photosensitive polyimide and the semiconductor die; and applying a second photosensitive polyimide over the first copper layer. The method may include patterning the second photosensitive polyimide; forming a second copper layer on the second photosensitive polyimide; and coupling one of a redistribution layer or another semiconductor die onto the second copper layer.

Implementations of a method of embedding a semiconductor die may include one, all, or any of the following:

The method may include forming a seed layer on the oxide layer before forming the thick copper layer.

The method may include filling a space around the semiconductor die with a polyimide before forming the first copper layer.

Forming the first copper layer further may include forming vias and traces at the same time.

Forming the first copper layer further may include first forming vias and then forming traces.

Forming the second copper layer further may include one of: forming vias and traces at the same time; or first forming vias and then forming traces.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a silicon substrate;

FIG. 2 is a cross sectional view of the silicon substrate of FIG. 1 with a redistribution layer formed thereon;

FIG. 3 is a cross sectional view of the silicon substrate of FIG. 1 with a redistribution layer and a backmetal layer formed thereon;

FIG. 4 is a perspective view of a silicon substrate mounted to a frame, a set of silicon substrates packed for shipping in a shipping package, and a cross sectional view of a set of silicon substrates arranged in the shipping package;

FIG. 5 is a cross sectional view of an implementation of a silicon substrate;

FIG. 6 is a cross sectional view of the silicon substrate of FIG. 5 after formation of a redistribution layer thereon;

FIG. 7 is a cross sectional view of the silicon substrate of FIG. 6 after formation of hollow vias therethrough;

FIG. 8 is a cross sectional view of an implementation of a silicon substrate;

FIG. 9 is a cross sectional view of the silicon substrate of FIG. 8 following formation of cavities therein and forming a thick copper layer thereon;

FIG. 10 is a cross sectional view of the silicon substrate of FIG. 9 following coupling of semiconductor die into the cavities and sintering thereof;

FIG. 11 is a cross sectional view of the silicon substrate of FIG. 10 following patterning of a photosensitive polymer layer thereon;

FIG. 12 is a cross sectional view of the silicon substrate of FIG. 11 following formation of a second copper layer thereon;

FIG. 13 is a cross sectional view of an implementation of a silicon substrate;

FIG. 14 is a cross sectional view of the silicon substrate of FIG. 13 following formation of a patterned thick copper layer thereon;

FIG. 15 is a cross sectional view of the silicon substrate of FIG. 14 following formation of a patterned photosensitive polyimide layer thereon;

FIG. 16 is a cross sectional view of the silicon substrate of FIG. 15 following sintering of semiconductor die to the patterned thick copper layer thereon;

FIG. 17 is a cross sectional view of the silicon substrate o FIG. 16 following formation of interconnects adjacent to the semiconductor die; and

FIG. 18 is a cross sectional view of the silicon substrate of FIG. 17 following formation of a second patterned photosensitive polyimide layer and a second copper layer thereon.

### DESCRIPTION

This disclosure, its aspects and implementations, are not limited to the specific components, assembly procedures or method elements disclosed herein. Many additional components, assembly procedures and/or method elements known in the art consistent with the intended power semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such power semiconductor packages, and implementing components and methods, consistent with the intended operation and methods.

Power semiconductor packages often include a substrate to which one or more semiconductor die are attached. The substrate includes traces that route electrical signals and includes a dielectric or other electrically non-conductive/insulative layer(s) that helps electrically isolate the layer that includes traces from other package components or a circuit board or other motherboard to which the power semiconductor package is attached. An example of a substrate is a direct bonded copper (DBC) substrate which can contain one layer of copper bonded to an electrically insulative layer or two layers of copper bonded on each largest planar side of an electrically insulative layer. One of the challenges of many substrate types is that the coefficient of thermal expansion differs between the material of the electrically insulative layer and the material of one or more semiconductor die that are bonded to the substrate. Furthermore, the need for good thermal performance to allow the one or more semiconductor die to be cooled during operation (particularly where the die are power semiconductor die) can also limit what types of electrically insulative materials can be used. Finally, the cost of the material for the electrically insulative material may be sufficiently high that a higher thermal performance of the material may be offset by the overall cost. For example, alumina (Al₂O₃) has a relatively low cost and has a thermal conductivity of 25 W/m*K. In contrast, aluminum nitride (AlN) is expensive and has a much higher thermal conductivity of 170 W/m*K. Silicon nitride (Si₃N₄) substrates are also expensive, but have a thermal conductivity of 90 W/m*K. HPS substrates (Alumina with ZrO₂ doping) are more expensive than alumina itself and have a similar thermal conductivity to alumina at 25 W/m*K, but offer better reliability than alumina. Direct bonded copper substrates employing electrically insulative layers with any of the foregoing materials do exhibit high ampacity, high break down voltage, and high heat conductivity relative to other insulators, but at reasonably high cost.

In this document, the use of silicon in combination with an oxide layer or other electrically insulative material layer thereon as a material for an electrically insulative layer in a substrate is disclosed. Silicon has a low cost given it is available at scale given its existing use as the primary substrate for various semiconductor die. Silicon has a higher thermal conductivity than alumina at 120 W/m*K and has essentially the same coefficient of thermal expansion as a semiconductor die that employs silicon as its substrate material. Silicon's coefficient of thermal expansion is also close to that of a semiconductor die that employs silicon carbide as its substrate material. Provided the oxide layer/other electrically insulative material layer is sufficiently thick, the silicon material can also provide reasonably high breakdown voltages. Other advantages of use of silicon include the ability to embed die using various existing silicon fabrication processes along with many choices for various solderable or sinterable metals for use forming electrically conductive layers on the front or back of the silicon layer. While the various implementations disclosed herein refer to the use of silicon as a substrate, these implementations could also be used as interposers in various package designs, thus utilizing silicon interposers to help build up the three dimensional structure of a semiconductor package in combination with other substrate types.

Referring to FIG. 1, an implementation of a silicon substrate 2 with an oxide (SiO₂ in this implementation) layer 4 thereon is illustrated. The silicon substrate 2 may be a full thickness substrate, meaning that its thickness is usually a function of the dimensions of the substrate. For example, a 300 mm diameter silicon substrate would have a thickness between about 775 microns to about 925 microns, a thickness determined by the need to prevent the substrate from drooping or warping excessively during ordinary semiconductor processing operations. In various implementations, however, the silicon substrate may be a thinned substrate, meaning that its thickness is less than ordinarily would have been determined for its size. The thickness of the oxide layer may be thick to help ensure that the desired break voltage for the silicon substrate is achieved. In various implementations, the oxide layer may be between about 0.1 microns to about 5 microns thick. Low voltage applications in the tens of volts may permit uses of oxide layers near the lower end of the thickness range while applications at very high voltages over 2000 V may employ oxide layer thicknesses at the high end of the range. While the use of an oxide layer is illustrated here, in various implementations, other dielectric materials could be employed to achieve the desired break down voltage such as, by non-limiting example, spin on glass, low k dielectric materials, nitrides, borophosphosilicate glass (BPSG), organic dielectrics, polyimides, benzocyclobutene, combinations of Si₃N₄ and SiO₂, metal oxides, tantalum oxide, hafnium oxide, aluminum oxide, or any other dielectric material.

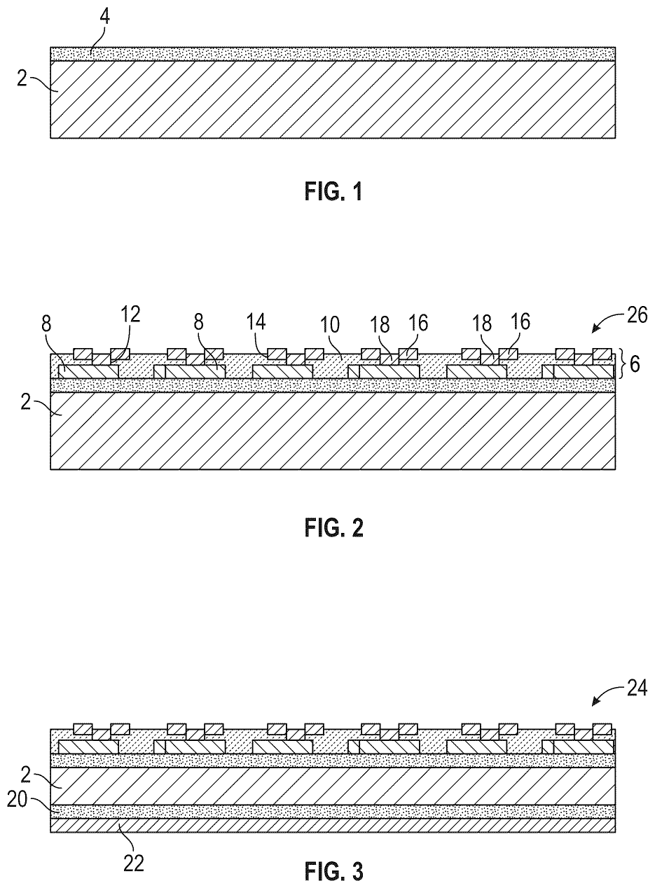

Referring to FIG. 2, the silicon substrate 2 of FIG. 1 is illustrated following formation of a redistribution layer 6 thereon. The process of formation of the redistribution layer includes formation of thick copper traces 8 on the oxide layer 4 initially. These thick copper traces may be between about 12 microns to about 35 microns thick in various implementations. The process of forming the thick copper traces 8 in various method implementations includes applying a copper adhesion layer to the oxide layer 4 which may include, by non-limiting example, one or more layers of tantalum, titanium, titanium nitride, titanium tungsten, chromium, any combination thereof, or other materials designed to facilitate adhesion of the thick copper traces 8 to the material of the oxide layer 4. The adhesion layer may be formed using sputtering, chemical vapor deposition, or electroless deposition in various method implementations. On the copper adhesion layer in various method implementations a copper seed layer is applied which may be formed using sputtering, electroless deposition, or electroplating in various implementations.

When the copper seed layer is formed, the surface is now ready for formation of the thick copper layer from which the thick copper traces are formed. The thick copper layer may be formed using an electroplating process, lamination process, sputtering process, or evaporation process. In some implementations, however, where a seed layer is not used, a copper foil may be applied/bonded/adhered/sintered/soldered to the adhesion layer where the copper foil has the desired thickness. Following formation of the thick copper layer, a patterned layer is formed over the thick copper layer using a lithographic process, screen printing, stenciling, dispensing, or another process of forming a pattern of traces on the thick copper layer. The thick copper layer is then etched to form the thick copper traces 8 (patterned layer of traces). In other method implementations, the use of a patterned layer may not be used, and instead the thick copper traces 8 may be formed using milling, lasering, or water jet cutting. Where lasering is used, a protective layer may be placed over the thick copper layer to help protect the resulting thick copper traces 8 from the slag created during the lasering process. The protective layer is then removed using a washing process to remove the slag with it and expose the thick copper traces 8.

While the use of thick copper has been illustrated thus far, the use of aluminum to form the thick traces could also be used. The aluminum could also be formed using any of the processes previously described consistent with depositing aluminum on the corresponding surfaces of the oxide layer or traces. The corresponding removal process for the aluminum may include any of the previous methods consistent with removing aluminum.

Following the formation of the thick copper traces 8, a dielectric material 10 is applied over the thick copper traces 8. A wide variety of materials may be utilized including, by non-limiting example, spin on glass, BPSG, polyimide, photodefinable polyimides, photodefinable polymers, low k dielectric materials, silicon dioxide, silicon oxynitride, any combination thereof, or any other dielectric material types capable of covering the thick copper traces 8 and forming a substantially planar surface. The processes used to form the dielectric material may include lamination, spray coating, curtain coating, or spin coating, depending on the particular material being used. In some method implementations, a planarizing process may be used on the dielectric material 10 to planarize the surface following application/formation of the dielectric material 10 thereon. Following the application/formation of the dielectric material 10, a set of openings 12, 14 are formed in the dielectric material 10. If the dielectric material 10 is a photodefinable polymer, then a lithography process may be used to create the openings 12, 14 directly. If the dielectric material is not photodefinable, in some implementations a patterned layer is formed on the dielectric material 10 and an etching process used to create the openings 12, 14. In yet other method implementations, a lasering or water jet cutting process may be employed to form/mill the openings 12, 14 in the dielectric material 10.

Following formation of the openings 12, 14, an electrically conductive material is used to fill the openings 12, 14 to form a second set of traces 16 with corresponding vias 18. The electrically conductive material may be copper in some implementations, and a damascene process (planar process) may be used to form the vias 18 and second set of traces 16 at the same time. In other implementations, the vias 18 may be formed first and then the traces formed using a patterning process similar to that used to form the thick copper traces 8 using a non-planar process. Other metals including gold, silver, aluminum, gold alloys, silver alloys, aluminum alloys, copper, copper alloys, or any combination thereof could be used in various implementations. Additional layers of traces and vias could also be formed in various implementations to form an interconnect stack that creates the redistribution layer that is composed of layers of electrically conductive and electrically non-conductive materials. The resulting layer allows for movement of electrical signals from the thick copper layers 8 to the second set of traces 16 and vice versa depending on how the substrate is electrically connected with one or more semiconductor die. In various implementations, a metal cap containing cobalt or another metal/metal stack designed to prevent diffusion of the copper into organic dielectric materials may be used. The resulting substrate 26 is illustrated in FIG. 2.

FIG. 3 illustrates the silicon substrate 2 following formation of another oxide layer 20 and a backmetal layer 22 thereon. In this implementation, the silicon substrate 2 has been thinned using a grinding, lapping, or other thinning process and the oxide layer 20 has been formed therein. The material of this oxide layer 20 may be any dielectric material disclosed in this document compatible with the back metal material. The backmetal layer 22 may include one or more layers of metal and may in various implementations include an adhesion layer. In some implementations, if the backmetal layer 22 is electroplated, a seed layer may also be present.

The resulting substrate/interposers 24, 26 are now ready for use in various semiconductor package types that can include, by non-limiting example, power modules, integrated power modules, leaded packages, leadless packages, inverters, power conversion equipment, or any other semiconductor package type that employs a substrate or interposer. These packages may be single side cooled or dual side cooled. A heat sink may be coupled with the backmetal layer 22 in various semiconductor package implementations as well. Also, the substrates 24, 26 may be utilized in wafer-scale packaging operations where they are singulated with one or more semiconductor die to which they have been bonded. The substrates 24, 26 may also be used in chip-scale packaging operations where the substrates 24, 26 have been singulated into smaller portions which then have semiconductor die attached to them. Where the substrates 24, 26 are already pre-singulated into the desired size, the substrates 24, 26 can be used in chip-scale packaging process where no further singulation of the substrates 24, 26 is carried out.

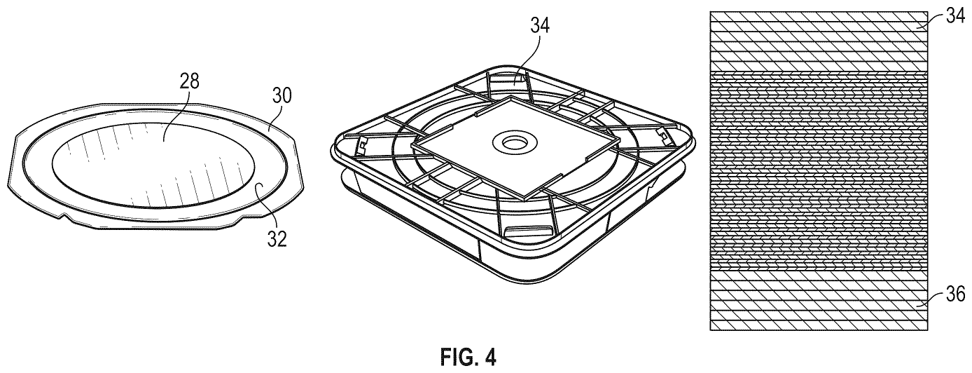

Any of the substrates 24, 26 formed at the substrate/panel/wafer level can be stored and transported to a subsequent location for additional processing. Referring to FIG. 4, a substrate 28 which is in the form of a silicon wafer has been mounted onto frame 30 using cutting tape 32. Now that the substrate 28 is mounted to the frame 30, a certain number of substrates can be packed in to shipping package 34. The drawing on the right side of FIG. 4 shows a cross sectional view of the contents of shipping package 34 which contains a stack of 25 frames with 26 interleaves between the frames to prevent contact between the cutting tape and the upper side of each substrate with six foam spacers 36 at the top and bottom to ensure the frames do not move. A wide variety of shipping techniques, shipping packages, and other transportation systems may be employed when shipping substrate implementations like those disclosed herein to other locations for additional semiconductor packaging operations.

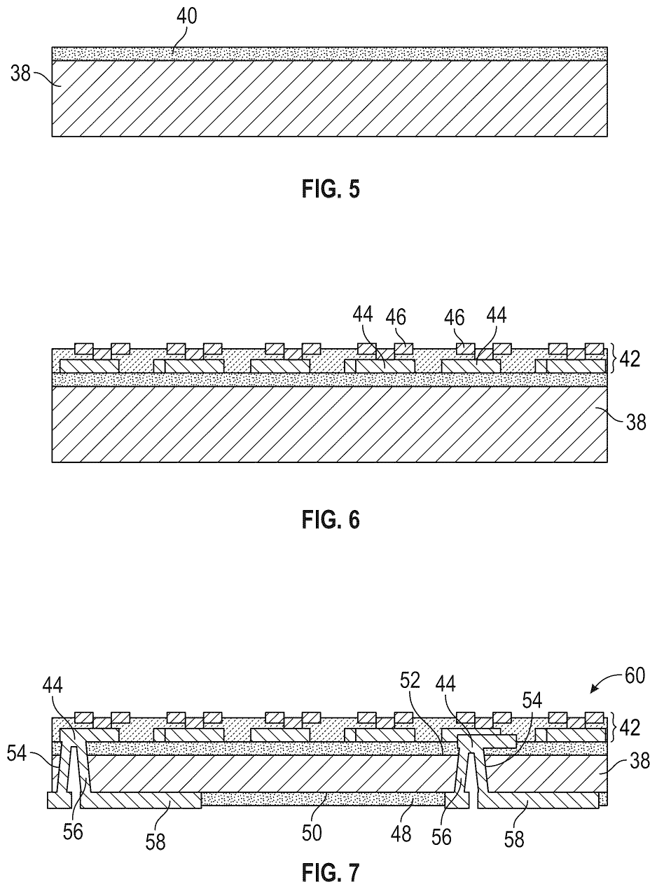

Referring to FIG. 5, another implementation of a silicon substrate 38 with an oxide layer 40 thereon is illustrated. FIG. 6 illustrates the silicon substrate 38 following formation of a redistribution layer 42 thereon that employs thick copper traces 44 and a second set of traces 46 similar to those illustrated in the substrate implementations in FIGS. 1-3. At this point, the substrate 38 is ready for additional processing. The processing begins by thinning the material of the substrate 38 to a desired thickness using any thinning process disclosed herein. Following the thinning, a layer of oxide 48 (or other dielectric material disclosed herein) is grown/formed on a second largest planar surface 50 of the substrate 38 that opposes a first largest planar surface 52 on which the redistribution layer 42 has been formed. The layer of oxide 48 is then pattered using a patterning layer formed on the oxide layer 48 using a lithography process or other patterning process disclosed herein and the oxide layer 48 is etched to expose the material of the silicon substrate 38. In the implementation illustrated in FIG. 7, a second patterned layer is then formed that outlines the locations of through silicon vias 54 prior to etching of the through silicon vias. As illustrated, the through silicon vias 54 are etched with slanted side walls that create a larger opening on the second largest planar side 50 of the silicon substrate 38 and narrower opening where the through silicon vias 54 meet the thick copper traces 44. This etching with slanted sidewalls may be accomplished using proper adjustments of the etching chemistry and chamber conditions and the thick copper traces 44 act as a etch stop for the through silicon vias 54.

Following the etching of the silicon, a copper adhesion layer that contains any of the materials previously disclosed in this document is applied. In some implementations, a copper barrier layer may also be formed into the through silicon vias 54 and exposed silicon. The copper barrier layer may include nickel or nickel vanadium in various implementations. In some method implementations, a seed layer is then applied over the barrier layer. In other method implementations, a thick copper layer 56 is then electroplated into the through silicon vias 54 and over other exposed areas of the silicon to form traces 58. The thickness of the thick copper layer 56 may be any thickness previously disclosed in this document. As illustrated in FIG. 7, the resulting through silicon vias 54 are hollow as the ends of the vias are not closed off. This ability to keep the through silicon vias 54 hollow may protect against damage to the vias during operation, particularly high temperature/amperage cycling which have been observed to cause copper pumping which causes cracking of the copper contained in solid through silicon vias. The ability for the resulting substrate 60 to allow for electrical connections to both sides of the substrate 60 through the through silicon vias 54 may make this substrate design particularly useful as an interposer in a semiconductor package design. The electrical connections may be any of a wide variety of electrical connector types including, by non-limiting example, wire bonds, bond wires, clips, wires, flexible connectors or any other electrical connector type. The electrically conductive materials utilized for the electrical connectors may be any of a wide variety of materials including, by non-limiting example, gold, gold alloys, silver, silver alloys, aluminum, aluminum alloys, copper, copper alloys, nickel, nickel alloys, any combination thereof, or any other electrically conductive material or alloy type. In various implementations, because thick copper traces are present on both sides of the silicon substrate 38, this substrate 60 may be an effective replacement for a direct bonded copper substrate. In various implementations, the through silicon vias 54 may be connected to fan out wiring formed by the traces 58. This would allow for various active and/or passive components to be coupled/bonded to both sides of the substrate 60, though from a processing perspective, this would take place after singulation of the semiconductor packages/substrate into package-sized portions.

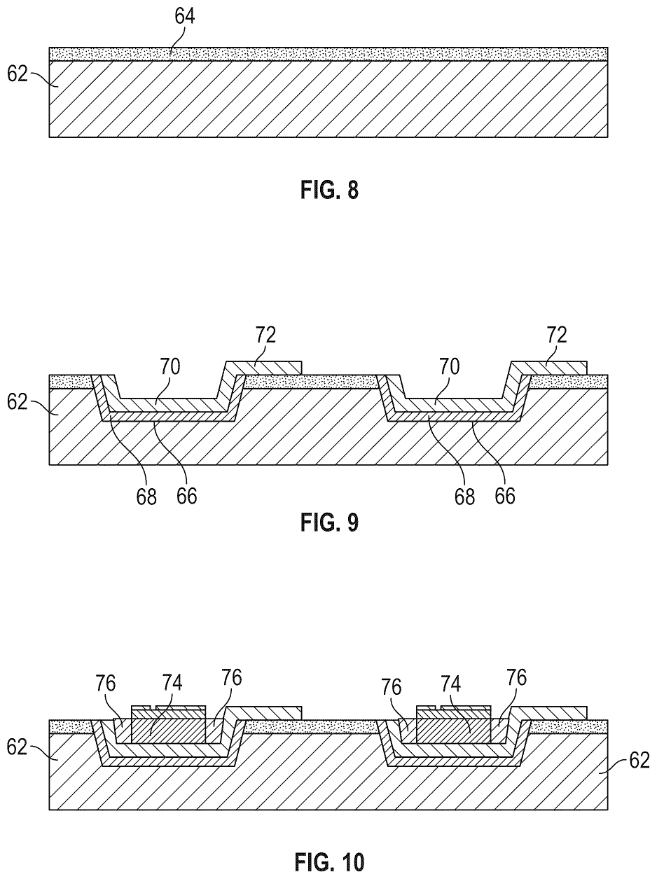

Various other substrate implementations disclosed herein may be formed using various methods of forming substrates/interposers. Referring to FIG. 8, a silicon substrate 62 is illustrated that includes an oxide layer 64 formed thereon. While an oxide layer 64 is illustrated, any of the other dielectric/non-electrically conductive materials disclosed herein could be employed in various substrate implementations as well. Referring to FIG. 9, the silicon substrate 62 is illustrated following formation of cavities 66 into the thickness/material of the silicon substrate 62. In various method implementations, the cavities 66 are formed by first forming a patterned layer over the oxide layer 64 and then etching the oxide to expose the surface of the silicon substrate. The patterned layer is then removed, and the oxide layer 64 is used as the patterned layer during an etching process used to remove the silicon and form the cavities 66. As illustrated, the etching process of the cavities 66 forms sloped edges indicating that the etch is more isotropic than anisotropic. Various etching processes including wet or dry etching may be employed to etch the cavities 66 to achieve the desired shape of the cavities. The use of sloped sidewalls assists with achieving more even formation of subsequent layers. While the use of etching has been disclosed, in some method implementations, the cavities 66 could be formed using lasering or milling processes, which could cut through both the oxide and the silicon at the same time and avoid the need to utilize formation of a patterned layer.

Following the formation of the cavities 66, another layer of oxide 68 is formed over the exposed silicon in the cavities 66. This oxide layer 68 may be formed using any of the methods disclosed herein and may be specifically formed as a conformal layer. In other implementations, however, the use of the oxide layer 68 may not be employed, but instead a barrier layer and/or seed layer may be applied to the exposed silicon. With the two oxide layers 64, 66 in place, a patterned layer is then formed at a desired height to facilitate formation of a thick copper layer 70 into the cavities along with copper trace portions 72. In the implementation illustrated in FIG. 9, a seed layer and/or barrier layer like any previously disclosed in this document are applied over the exposed oxide layers 64, 66 and then an electroplating process is used to form a thick copper layer 72 and corresponding copper trace portions 72 like any disclosed herein. In other implementations, any of the other disclosed methods of forming a thick copper layer may also be used to form the thick copper layer. Following formation of the thick copper layer 70 and any corresponding copper trace portions 72, the pattered layer is then removed. A wide variety of thick copper structures extending into, out of, and which just form traces on the surface of the oxide layers 64, 66 may be formed using the principles disclosed in this document.

While the use of copper is disclosed in the method implementation illustrated in FIG. 9, the use of any other metal or metal alloy disclosed herein applied using any of the corresponding methods of forming that metal may be used in other method implementations. Multiple layers of metal of different types or the same type may be utilized in some method implementations as well.

Referring to FIG. 10, the silicon substrate 62 is illustrated following bonding of semiconductor die 74 therein. In this implementation, the semiconductor die 74 are placed into cavities 66 on the thick copper layer 72 and then sintered either directly or using a sintering material compatible with forming a bond between the surface of the semiconductor die 74 and the thick copper layer 70. In other method implementations, the semiconductor die 74 may be soldered to the thick copper layer 70 by dispensing a solder material onto either the semiconductor die 74 or thick copper layer 70 or both and then heating the silicon substrate 62 to melt the solder and form the desired bond. A wide variety of solder materials could be used depending on the material(s) of the semiconductor die 74 and the desired processing conditions and bond including by non-limiting example, lead tin solder, lead silver tin solder, tin silver solder, tin copper solder, tin, any combination thereof or another solder material compatible with any metallic layer(s) on the semiconductor die and the thick copper layer or other metal layer in the bottom of the cavities 66. In implementations where a solder is used, a solder adhesion metal layer may be first formed over the thick copper layer 70 which may be, by non-limiting example, titanium, titanium tungsten, tantalum, titanium nitride, chromium, any combination thereof, or another metal or material that facilitates adhesion between the particular solder and the particular metal type to which the solder is being attached. Other materials/bonding systems could be used to attach the semiconductor die to the thick copper layer 70 including, by non-limiting example, die attach film, glue, die attach adhesives, a friction fit, a mechanical fit, or any other system/method for attaching a semiconductor die into a cavity.

FIG. 10 illustrates how, after the semiconductor die 74 have been bonded to the thick metal layer 70, the edge gaps around the semiconductor die 74 and the thick metal layer 70 in the cavities 66 has been filed with a fill material. In this implementation, the fill material may be a polyimide material 76 dispensed using an ink jet printing method, a needle dispense method, or other precision dispensing methods followed by a baking operation to cure the polyimide material 76 in the edge gaps. In other implementations, other materials to fill the edge gaps may be utilized including, by non-limiting example, polymers, resins, mold compound, or other electrically insulative materials which may be cured using the corresponding curing method.

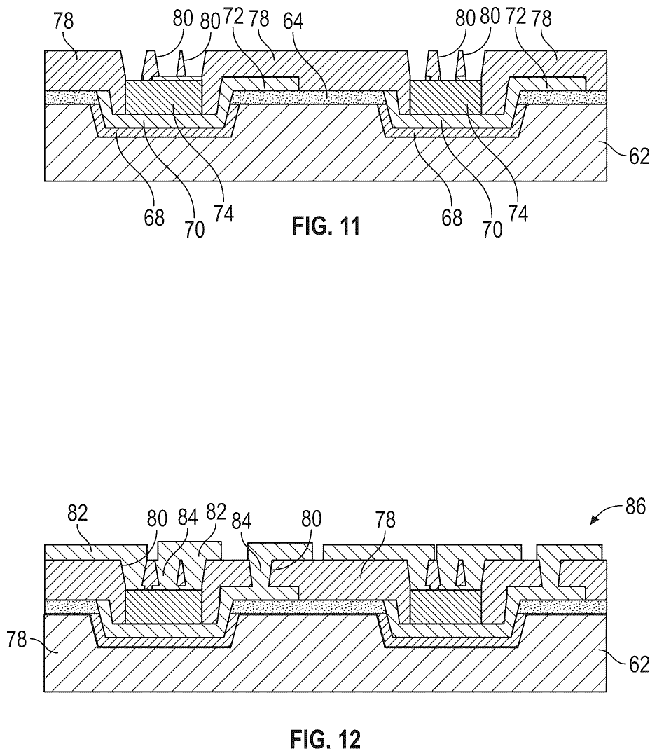

Referring to FIG. 11, the silicon substrate 62 is illustrated following spin coating of a photosensitive polymer layer 78 over the semiconductor die 74, oxide layers 64, 68, thick copper layer 70 and copper trace portions 72 following by light exposure and development to form openings 80 over desired portions of the semiconductor die 74 and/or copper trace portions 72. In this implementation a curing process is used to finish curing the photosensitive polymer layer 78 so it is prepared to remain in place during subsequent operations. While the use of spin coating of the photosensitive polymer is illustrated in the method implementation of FIG. 11, any other method of forming a polymer layer disclosed herein could be employed consistent with the particular polymer/resin material being used to form the polymer layer.

FIG. 12 illustrates the silicon substate 62 of FIG. 11 following formation of copper traces 82 and vias 84 into the openings 80 of the photosensitive polymer layer 78. The formation of the copper traces 82 and vias 84 may be accomplished by first using a sputtering process to form a seed layer over the photosensitive polymer layer 78 followed by electroplating. In this method, the vias and the traces can be formed at the same time in a damascene (planar) fashion. Following electroplating, a lithography process can be employed to form a patterned layer over the copper traces 82 and then an etching process used to complete the formation of the copper traces 82. In other method implementations, however, a planarizing step may be utilized prior to the lithography process to create smoother copper traces. Where other metals are employed, the appropriate deposition, via fill, and trace formation operations for those metals may be employed. In various implementations, the vias may be formed first using metals different from the traces or the same, depending on the process used. At this point, the resulting substrate 86 is ready for use in further semiconductor processing operations. For example, one or more additional redistribution layers could be formed over the copper traces 82 (second copper layer) to form an interconnect stack. One or more additional semiconductor die could be coupled to the copper traces 82 as well and exposed through a mold compound or further embedded in additional redistribution layers. In various semiconductor packages, multiple substrates 86 could be included in stacked or otherwise joined configurations in multichip modules. Finally, the substrate 86 could be thinned and/or backmetal added using any of the processing method disclosed for either operation disclosed in this document.

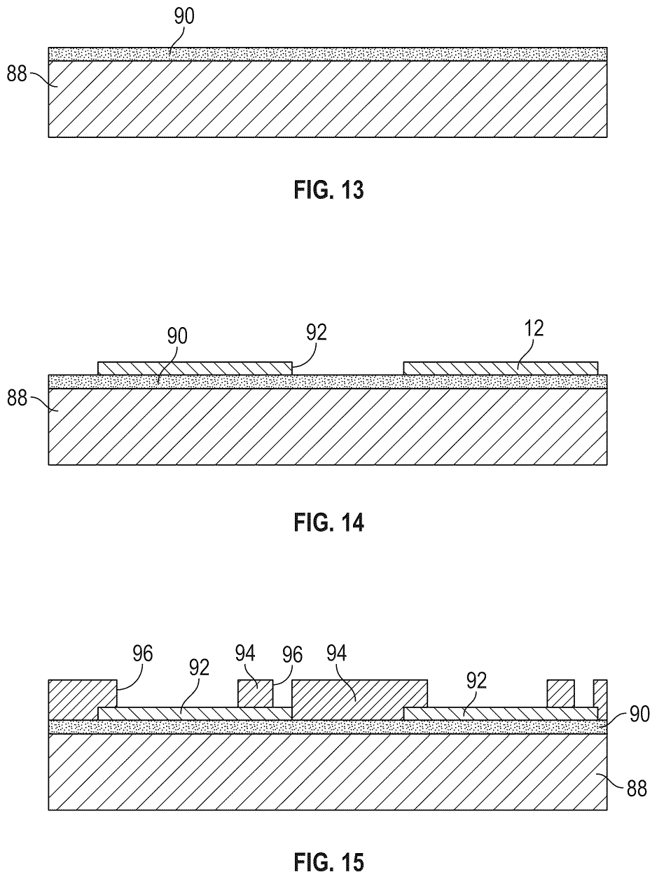

Referring to FIG. 13, an implementation of a silicon substrate 88 with an oxide layer 90 thereon is illustrated. While the use of an oxide layer is illustrated in this method implementation, any of the previously disclosed dielectric materials could be employed. In this implementation, a patterned layer of thick copper traces 92 are then formed over the oxide layer 90. This patterned layer begins with deposition of an adhesion and/or seed layer followed by electroplating/formation of a thick copper layer using any of the layer types and formation/deposition methods disclosed in this document for the various layers. A patterned layer is then formed over the thick copper layer and then an etching/removal process like any disclosed herein carried out to remove the thick copper layer in the exposed regions to form the thick copper traces 92. Where etching is not employed, a milling/lasering process could also be used to form the thick copper traces. If a lasering process is employed, a protective coating may be formed over the thick copper layer to retain slag thereon which can then be removed through washing or another cleaning process. The resulting structure is illustrated in FIG. 14, where thick copper traces 92 are illustrated and portions of the oxide layer 90 are exposed.

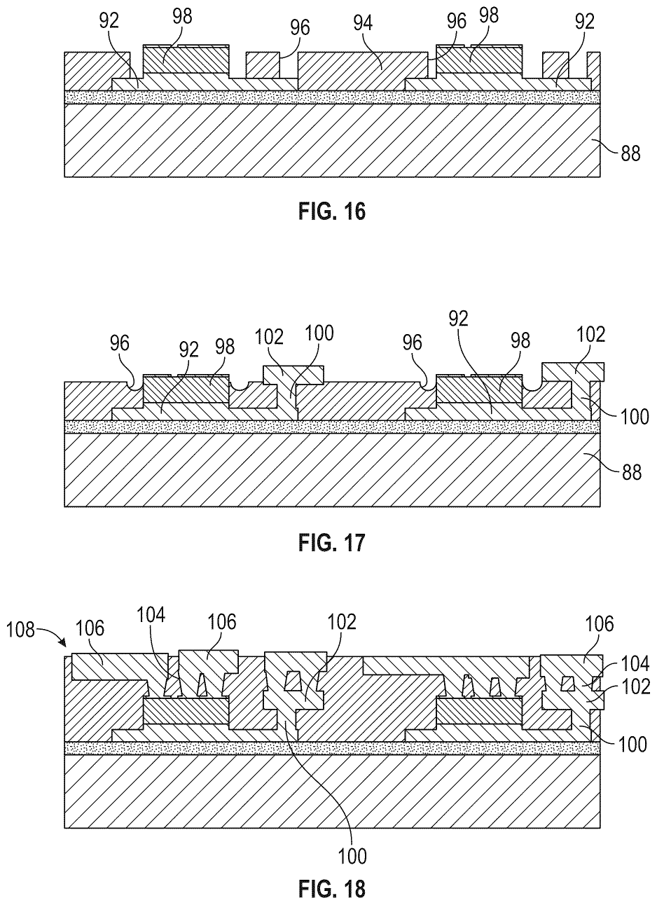

Referring to FIG. 15, the silicon substrate 88 is illustrated following vacuum lamination of a photosensitive polyimide (PSPI) layer 94 over the thick copper traces 92 and the oxide layer 90. Because the polyimide is photodefinable, after the layer has been formed conformally over the surface of the silicon substrate 88, exposure to light and development of the reacted PSPI material to create openings 96 is carried out. FIG. 16 illustrates the silicon substrate 88 following bonding of semiconductor die 98 into the openings 96 onto the thick copper traces 92. The bonding may take place using any die bonding method disclosed herein including sintering and soldering.

Referring to FIG. 17, the silicon substrate 88 is illustrated following a precision filling operation of the gaps between the openings 96 and the semiconductor die 98 using any filling material and process disclosed herein. A baking/curing process is then used to stabilize the filling material. Vias 100 and copper traces (second copper layer) 102 are then formed to form electrical connections with the thick copper traces 92. The vias 100 and copper traces 102 may be formed using any method of forming copper layers disclosed herein. Other metals/electrically conductive materials other than copper could be used for the vias 100 and/or traces 102 in various implementations using deposition and formation methods consistent with those metals.

FIG. 18 illustrates the silicon substrate 88 following application of another layer of photodefinable polyimide/photodefinable polymer using any method disclosed herein over the vias 100 and traces 102 and the formation of a second set of vias 104 and third set of copper traces 106 thereon/therein. Additional electrically conductive and non-electrically conductive layers could be formed to perform additional electrical routing to another semiconductor die coupled to the traces 102. In this way, the semiconductor die 98 are embedded in the resulting substrate 108. The substrate 108 can then be used in packaging operations to form any of the previously disclosed semiconductor package types including multichip modules. The substrate 108 can also be thinned and/or have backmetal applied. Where the substrates 86 and 108 have metal/electrically conductive layers on both sides, they can effectively be used for mounting of active and/or passive components to both sides of the substrates following any singulation that may need to be carried out.

In the present document, the semiconductor die that may be used may be any of a wide variety including, by non-limiting example, power semiconductor die, diodes, metal oxide field effect transistors (MOSFETs), insulated gate bipolar junction transistors (IGBTs), hybrid devices, rectifiers, random access memory, high-electron-mobility transistors, image sensors, wide bandgap (WBG) semiconductor devices, hybrid devices, or any other semiconductor die/device type. Any of a wide variety of semiconductor substrate types may be employed for the semiconductor die packaged using the semiconductor package designs disclosed in this document including, by non-limiting example, silicon, silicon carbide, gallium arsenide, gallium nitride, silicon on insulator, ruby, sapphire, or any other semiconductor material type. A wide variety of semiconductor package configurations may be formed using the principles disclosed herein.

The various semiconductor packages that incorporate the various substrate implementations disclosed herein may be cooled from one side or both sides of the packages (double sided cooling). Also, the methods for embedding semiconductor die disclosed herein may be utilized to embed multiple semiconductor die in multiple layers of the same substrate or in combinations of multiple substrates.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A substrate comprising:
a semiconductor material;
a redistribution layer coupled to a first largest planar surface of the semiconductor material; and
a hollow via extending from a second largest planar surface of the semiconductor material completely through a thickness of the semiconductor material, the hollow via directly coupled with the redistribution layer.

2. The substrate of claim 1, wherein the redistribution layer comprises at least one thick copper layer.

3. The substrate of claim 1, wherein the redistribution layer comprises at least one dielectric layer and at least one layer of one of a solderable metal or a sinterable metal.

4. The substrate of claim 1, wherein the semiconductor material is thinned from an initial thickness.

5. The substrate of claim 1, wherein the semiconductor material is silicon carbide.

6. The substrate of claim 1, wherein the semiconductor material is silicon.

7. The substrate of claim 6, further comprising an oxide layer between the redistribution layer and the semiconductor material.

8. The substrate of claim 6, further comprising an oxide layer on the second largest planar surface of the semiconductor material.

9. The substrate of claim 1, further comprising a backmetal layer coupled to the second largest planar surface of the semiconductor material.

10. A method of embedding a semiconductor die, the method comprising:
providing a silicon substrate comprising a first oxide layer thereon;
forming at least one opening in the first oxide layer;
etching a cavity into the silicon substrate at the at least one opening in the first oxide layer;
forming a second oxide layer in the cavity;
forming a thick copper layer on the first oxide layer and on the second oxide layer;
patterning the thick copper layer;
sintering at least one semiconductor die to the thick copper layer in the cavity;
filling a gap between the at least one semiconductor die and the thick copper layer in the cavity with a polyimide;
forming a layer of photosensitive polymer over the at least one semiconductor die, the thick copper layer, and the first oxide layer;
patterning the layer of photosensitive polymer to form a plurality of openings therein;
forming a first copper layer in the plurality of openings; and
forming a second copper layer over the layer of photosensitive polymer and the first copper layer.

11. The method of claim 10, wherein forming the first copper layer and forming the second copper layer occur simultaneously.

12. The method of claim 10, further comprising forming a seed layer on the second oxide layer before forming the thick copper layer.

13. The method of claim 10, further comprising baking the polyimide.

14. The method of claim 10, further comprising coupling one of a redistribution layer or another semiconductor die to the second copper layer.

15. A method of embedding a semiconductor die, the method comprising:
providing a silicon substrate comprising an oxide layer thereon;
forming a thick copper layer on the oxide layer;
patterning the thick copper layer;
applying a first photosensitive polyimide over the thick copper layer;
patterning the first photosensitive polyimide to form an opening therein;
one of sintering or soldering a semiconductor die in the opening;
forming a first copper layer on the first photosensitive polyimide and the semiconductor die;
applying a second photosensitive polyimide over the first copper layer;
patterning the second photosensitive polyimide;
forming a second copper layer on the second photosensitive polyimide; and
coupling one of a redistribution layer or another semiconductor die onto the second copper layer.

16. The method of claim 15, further comprising forming a seed layer on the oxide layer before forming the thick copper layer.

17. The method of claim 15, further comprising filling a space around the semiconductor die with a polyimide before forming the first copper layer.

18. The method of claim 15, wherein forming the first copper layer further comprises forming vias and traces at the same time.

19. The method of claim 15, wherein forming the first copper layer further comprises first forming vias and then forming traces.

20. The method of claim 15, wherein forming the second copper layer further comprises one of:
forming vias and traces at the same time; or
first forming vias and then forming traces.
